(19) United States
(12) Patent Application Publication
(10) Pub. No.: US 2024/0429090 A1
(43) Pub. Date: Dec. 26, 2024

(54) Contact Feature Through Heterogeneous Stacked Film and Methods of Making Same

(71) Applicant: Taiwan Semiconductor Manufacturing Company, Ltd., Hsin-Chu (TW)

(72) Inventors: Yao-Jhen Yang, Hsinchu City (TW); Jiann-Horng Lin, Hsinchu City (TW); Chung Ta Han, Taipei City (TW); Hsiang-Ku Shen, Hsinchu City (TW)

(21) Appl. No.: 18/337,882

(22) Filed: Jun. 20, 2023

(51) Int. Cl. H01L 21/768; H01L 21/02; H01L 21/311; H01L 21/3213; H01L 23/522; H01L 23/528; H01L 23/532

(52) U.S. Cl. CPC H01L 21/76814; H01L 21/02063; H01L 21/31116; H01L 21/32139; H01L 21/76877; H01L 23/5223; H01L 23/5226; H01L 23/5283; H01L 23/53266

(57) ABSTRACT

A method includes providing a workpiece. The workpiece includes a substrate, a first dielectric layer over the substrate, a lower contact feature vertically extending through the first dielectric layer, a second dielectric layer over the lower contact feature and the first dielectric layer, a third dielectric layer over the second dielectric layer, a metal-insulator-metal (MIM) structure over the third dielectric layer, and a fourth dielectric layer over the MIM structure. The method further includes performing a first etch process to form an opening through the fourth dielectric layer to expose the MIM structure; performing a second etch process to extend the opening through the MIM structure to expose the third dielectric layer; performing a third etch process to further extend the opening into the third dielectric layer; and performing a fourth etch process to further extend the opening through the second dielectric layer to expose the lower contact feature.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

As the geometry size of IC devices decreases, passive devices that require large surface areas are moved to back-end-of-line (BEOL) structures. Metal-Insulator-Metal (MIM) capacitors are among examples of such passive devices. A typical MIM capacitor includes multiple conductor plate layers that are insulated from one another by multiple insulator layers. Contact vias are formed through an MIM capacitor. The formation of the contact vias requires forming an opening through the MIM capacitor as well as dielectric layers overlying and underlying the MIM capacitor. Forming the opening often results in a stepped structure, which may impact conformity of a barrier layer and/or a seed layer deposited on sidewalls of the opening. Therefore, although existing MIM structures and the fabrication process thereof have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor device in accordance with embodiments of the present disclosure.

FIGS. 2, 3, 4, 5, 6, 7, 8, and 10 are fragmentary cross-sectional views of a semiconductor device at various stages of fabrication according to embodiments of the present disclosure.

FIGS. 9A, 9B, and 9C are fragmentary cross-sectional views of openings through conductor plate layers in an MIM structure in accordance with embodiments of the present disclosure.

FIG. 11 is a fragmentary top view of the semiconductor device in accordance with embodiments of the present disclosure.

### DETAILED DESCRIPTION

It is understood that the following disclosure provides many different embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments, in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the sake of simplicity and clarity and does not in itself dictate a relationship between the various embodiments and/or configurations discussed. Moreover, various features may be arbitrarily drawn in different scales for the sake of simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Metal-Insulator-Metal (MIM) capacitors (also referred to as MIM structures) have been widely used in functional circuits such as mixed signal circuits, analog circuits, Radio Frequency (RF) circuits, Dynamic Random Access Memories (DRAMs), embedded DRAMs, and logic operation circuits. In system-on-chip (SOC) applications, different capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling. As its name suggests, an MIM capacitor includes a sandwich structure of interleaving metal layers (also referred to as conductor plate layers) and insulator layers. An example MIM capacitor includes a bottom conductor plate layer, a middle conductor plate layer over the bottom conductor plate layer, and a top conductor plate layer over the middle conductor plate, each of which is insulated from an adjacent conductor plate layer by an insulator layer. As an MIM capacitor is fabricated in a BEOL structure to have a larger surface area, its conductor plate layers extend over multiple lower contact features. Contact vias may be formed through the conductor plate layers to electrically couple the lower contact features to upper contact features, such as contact pads, for connection to external circuitry.

Openings for the contact vias may penetrate the conductor plate layers and the insulator layers of the MIM capacitor and dielectric layers overlying and underlying the MIM capacitor. Before depositing a conductive filler material, a barrier layer and/or a seed layer may be deposited in the openings. Uniformity of the barrier layer and/or the seed layer may impact reliability level to prevent the conductive filler material from penetrating into the MIM capacitor, which may cause voltage breakdown. In addition, the openings in a same semiconductor device may have different dimensions (e.g., widths, lengths, diameters) for forming contact vias having different dimensions therein. The different dimensions may cause uneven etching rates, which may lead to defects.

Conventionally, fluorine-based etchants (e.g., sulfur hexafluoride (SF₆)) are used to etch through conductor plate layers as well as the overlying and underlying dielectric layers. It has been observed that the conventional etch processes may produce metal fluoride as byproducts (hereinafter “metal fluoride byproducts”). For example, the etching of titanium nitride conductor plate layers may produce titanium fluoride (TFₓ, X=3 or 4). Metal fluoride byproducts are non-volatile and may not be removed during the etch process. As the conductor plate layers are being etched, such metal fluoride may be redeposited onto the newly etched surfaces and slows down the etch process. Oftentimes the redeposition of the metal fluoride may result in stepped sidewalls of the openings because the redeposition is likely to take place when the etching process progresses toward lower conductor plate layers. In side views, contact vias formed using conventional processes may be characterized by a steep taper followed by a shallow taper as the contact vias penetrate the MIM capacitors. In addition, residual metal fluoride byproducts may remain at the interface between the conductor plate layers and the contact vias. The residual metal fluoride byproducts may be redeposited on the dielectric layer underlying the conductor plate layers to slow down the etching rate through the underlying dielectric layer, resulting in dishing of the underlying dielectric layer. The dishing of the underlying dielectric layer may lead to uneven etching through the etch stop layer (ESL) that underlies the underlying dielectric layer. The presence or absence of residual metal fluoride byproducts at the interface may be observed or verified by energy-dispersive X-ray spectroscopy (EDX).

The present disclosure provides a method to form openings having substantially linear sidewalls in cross-sectional profiles in a semiconductor device. The method of the present disclosure forms openings through the MIM structure (as well as overlying and underlying dielectric layers and an etch stop layer (ESL)) using multiple etch processes. In some embodiments, a first etch process etches through the overlying dielectric layer using a first fluorine-containing etchant, a second etch process etches through the MIM structure using a chlorine-containing etchant, a third etch process etches into the underlying dielectric layer using a second fluorine-containing etchant, and then a fourth etch process etches through the underlying dielectric layer and the etch stop layer using the second fluorine-containing etchant. A non-zero bias power and a non-zero source power are applied to the semiconductor device during the fourth etch process. A wet cleaning process is performed to smooth profiles of the openings after the fourth etch process and before forming contact vias in the openings. Methods of the present disclosure may form a contact via having a substantially linear taper.

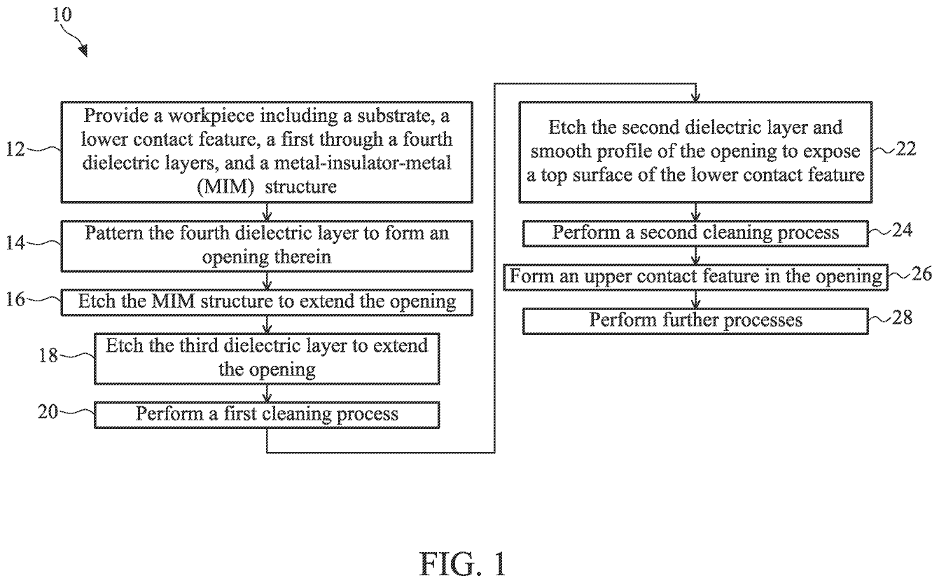

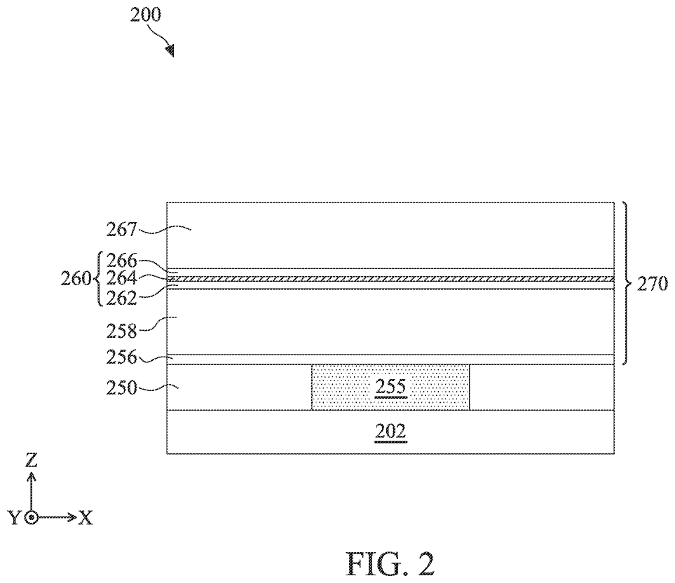

The various aspects of the present disclosure will now be described in more detail with reference to the figures. In that regard, FIG. 1 is a flowchart illustrating a method 10 for fabricating a semiconductor device according to embodiments of the present disclosure. Method 10 is merely an example and is not intended to limit the present disclosure to what is explicitly illustrated in method 10. Additional steps can be provided before, during, and after method 10, and some steps described can be replaced, eliminated, or moved around for additional embodiments of the method. Not all steps are described herein in detail for reasons of simplicity. Method 10 is described below in conjunction with FIGS. 2-8 and 10, which are diagrammatic fragmentary cross-sectional views of the semiconductor device at different stages of fabrication according to embodiments of the present disclosure.

Referring to FIGS. 1 and 2, method 10 includes a block 12 where a workpiece 200 is provided. The workpiece 200 includes various layers already formed thereon. Because a semiconductor device will be formed from the workpiece 200, workpiece 200 may be referred to as semiconductor device 200 in suitable context. The workpiece 200 includes a substrate 202, which may be made of silicon or other semiconductor materials such as germanium. The substrate 202 also may include a compound semiconductor such as silicon carbide, gallium arsenic, indium arsenide, or indium phosphide. In some embodiments, the substrate 202 may include alloy semiconductor such as silicon germanium, silicon germanium carbide, gallium arsenic phosphide, or gallium indium phosphide. In some embodiments, the substrate 202 may include an epitaxial layer, for example an epitaxial layer overlying a bulk semiconductor. Various microelectronic components may be formed in or on the substrate 202, such as transistor components including source/drain features, gate structures, gate spacers, source/drain contacts, gate contacts, isolation structures including shallow trench isolation (STI), or any other suitable components.

In some embodiments, the workpiece 200 includes an interconnect layer, a carbide layer, and/or an oxide layer over the substrate 202. In the interest of simplicity such layers or components are not shown. The interconnect layer may be one of the interconnect layers in a multi-layered interconnect (MLI) structure, which is formed over the substrate 202 and may include multiple patterned dielectric layers and conductive layers that provide interconnections (e.g., wiring) between the various microelectronic components of the workpiece 200. The interconnect layer may include multiple conductive components as well as an interlayer dielectric (ILD) component that partially or fully surrounds the conductive components. In an embodiment, the carbide layer is deposited on the interconnect layer. Any suitable type of carbide material such as silicon carbide (SiC) can be used in the carbide layer. In an embodiment, the oxide layer is deposited on the carbide layer. In some embodiments, the oxide layer includes undoped silicon oxide. In an embodiment, the interconnect layer, the carbide layer, and the oxide layer may be replaced with one or more interconnect structures.

In some embodiments, the workpiece 200 includes a first dielectric layer 250 deposited over the substrate 202. In some embodiments, the first dielectric layer 250 includes undoped silica glass (USG) or silicon oxide. In some embodiments, the first dielectric layer 250 includes USG. In some embodiments, the first dielectric layer 250 is about 800 to about 1000 nm thick.

In some embodiments, the workpiece 200 includes a lower contact feature 255 embedded in the first dielectric layer 250. Although the lower contact feature 255 is below an upper contact feature (to be discussed below), the lower contact feature 255 is sometimes referred to as a top metal (TM) contact because it may reside above transistor features (not shown in figures herein). The lower contact feature 255 may vertically extend through the first dielectric layer 250. The lower contact feature 255 may include a barrier layer and a metal fill layer embedded in the barrier layer. Forming the lower contact feature 255 involves multiple processes. The first dielectric layer 250 may be patterned to form a trench, for example, using a photolithography process. The barrier layer may then be formed in the trench, followed by deposition of the metal fill layer over the barrier layer in the trench. In some embodiments, the barrier layer includes titanium nitride, tantalum, tantalum nitride, or combinations thereof. In some embodiments, the metal fill layer includes a metal or metal alloy such as copper, cobalt, nickel, aluminum, tungsten, titanium, or combinations thereof. In one embodiment, the metal fill layer of the lower contact feature 255 includes copper. In some embodiments, the metal fill layer is formed by deposition or plating, followed by a chemical mechanical planarization (CMP) process. In an embodiment, about 5% to about 10% of the thickness of the first dielectric layer 250 is also removed by the CMP process.

In some embodiments, the workpiece 200 includes a second dielectric layer 256 deposited over the lower contact feature 255. The second dielectric layer 256 may also be referred to as an etch stop layer (ESL) 256. In some embodiments, the second dielectric layer 256 is about 65 to about 85 nm thick. The second dielectric layer 256 may include silicon carbonitride (SiCN), silicon nitride (SiN), silicon oxycarbide (SiOC), silicon carbide (SiC), silicon oxycarbonitride (SiOCN), and/or or other suitable materials. In some embodiments, the second dielectric layer 256 includes SiCN. The second dielectric layer 256 serves to indicate etching end in an etching process.

In some embodiments, the workpiece 200 includes a third dielectric layer 258 deposited over the second dielectric layer 256. In some embodiments, the third dielectric layer 258 is about 300 to about 500 nm thick. In embodiments, the third dielectric layer 258 includes a suitable dielectric material such as SiN.

In some embodiments, the workpiece 200 includes a metal-insulator-metal (MIM) structure 260 formed over the third dielectric layer 258. Forming the MIM structure 260 involves multiple processes, including those for formation and patterning of conductor plate layers (e.g., a bottom conductor plate layer 262 and a top conductor plate layer 266).

In some embodiments, forming the bottom conductor plate layer 262 involves multiple processes such as deposition, photolithography, development, and/or etching, etc. The bottom conductor plate layer 262 may go through surface treatment such as sidewall passivation using a nitrous oxide (N₂O) gas. As shown in FIG. 2, an insulator layer 264 is formed on the bottom conductor plate layer 262. In an embodiment, the insulator layer 264 is deposited to have a generally uniform thickness over the top surface of the workpiece 200. Then, the top conductor plate layer 266 is formed on the insulator layer 264. The top conductor plate layer 266 may be formed in a way similar to that used to form the bottom conductor plate layer 262. In some embodiments, the bottom conductor plate layer 262 and the top conductor plate layer 266 are each about 30 nm to about 80 nm thick. In some embodiments, to prevent electromigration and oxygen diffusion, the conductor plate layers (e.g., the bottom conductor plate layer 262 and the top conductor plate layer 266) in the MIM structure 260 may be formed of a transition metal or a transition metal nitride. For example, the conductor plate layers in the MIM structure 260 may be formed of titanium (Ti), tantalum (Ta), titanium nitride (TiN), or tantalum nitride (TaN). In embodiments, the conductor plate layers include TiN.

Although only two conductor plate layers (the conductor plate layers 262 and 266) and one insulator layer (the insulator layer 264) are depicted, the MIM structure 260 may include more than two conductor plate layers and more than one insulator layer. Each of the conductor plate layers is insulated from an adjacent conductor plate layer by an insulator layer. In some embodiments, the MIM structure 260 includes multiple conductor plate layers including the bottom conductor plate layer 262 and the top conductor plate layer 266, which function as metal plates of capacitors. The MIM structure 260 may also include multiple insulator layers including the insulator layer 264 disposed between the bottom conductor plate layer 262 and the top conductor plate layer 266. The MIM structure 260 is used to implement one or more capacitors, which may be connected to other electric components such as transistors. The multi-layer MIM structure 260 allows capacitors to be closely packed together in both vertical and lateral directions, thereby reducing the amount of lateral space needed for implementing capacitors. As a result, the MIM structure 260 may accommodate super high density capacitors.

In some embodiments, to increase capacitance values, the insulator layer 264 includes high-k dielectric material(s) whose k-value is greater than that of silicon oxide. The insulator layer 264 may be relatively thin to increase capacitance values. However, minimal thickness for the insulator layer 264 is maintained to avoid potential breakdown of the capacitor in the MIM structure 260 (e.g., when the two conductor plate layers have high potential difference, current may leak therebetween, causing breakdown). In some embodiments, the insulator layer 264 is about 4 nm to about 20 nm thick. In some implementations, the insulator layer 264 is formed of zirconium oxide (ZrO₂), hafnium oxide (HfO₂), aluminum oxide (Al₂O₃), tantalum oxide (TaO₅), silicon oxide (SiO₂), or titanium oxide (TiO₂). Further, to optimize the capacitor performance, in some embodiments, the insulator layer 164 is a tri-layer structure including, from bottom to top, a first zirconium oxide (ZrO₂) layer, an aluminum oxide (Al₂O₃) layer, and a second zirconium oxide (ZrO₂) layer, where each of the sub-layers has the same thickness.

In some embodiments, the workpiece 200 includes a fourth dielectric layer 267 deposited over the MIM structure 260. In some embodiments, the fourth dielectric layer 267 is about 400 to about 500 nm thick. In some embodiments, the third dielectric layer 258 includes a suitable dielectric material such as SiN. In some embodiments, the fourth dielectric layer 267 is formed by depositing about 900 to about 1000 nm of the dielectric material, followed by a CMP process to reach the final thickness. As shown in FIG. 2, the MIM structure 260 is sandwiched between the third dielectric layer 258 and the fourth dielectric layer 267, which may have the same material and/or the same thickness. In some embodiments, the second dielectric layer 256, the third dielectric layer 258, the MIM structure 260, and the fourth dielectric layer 267 are regarded as parts of a passivation structure 270.

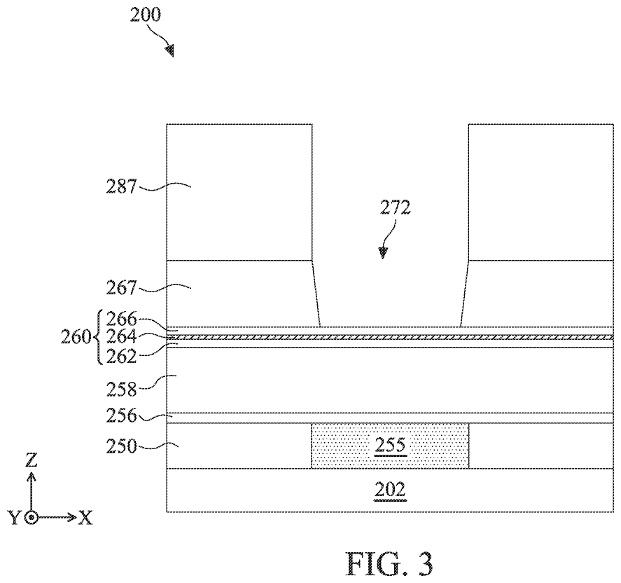

Referring to FIGS. 1 and 3, method 10 includes a block 14 where the fourth dielectric layer 267 is patterned and etched through to form an opening 272. The patterning may include deposition of a hard mask layer 287 over the first conductive layer 262, formation of a photoresist layer (not depicted) over the hard mask layer, patterning of the photoresist layer using photolithography, etching of the hard mask layer 287 using the patterned photoresist layer as an etch mask, and then etching the fourth dielectric layer 267 using the patterned hard mask layer 287 as an etch mask. The etching of the fourth dielectric layer 267 may also be referred to as a first etch process. The first etch process etches through the fourth dielectric layer 267 at a homogeneous rate, resulting in a linear taper profile of a sidewall of the fourth dielectric layer 267. The first etch process is time-controlled such that it terminates at a top surface of the top conductor plate layer 266. The first etch process may be a dry etch process using a first etchant. In embodiments, the first etchant is a fluorine-based etchant and includes sulfur hexafluoride (SF₆), nitrogen trifluoride (NF₃), difluoromethane (CH₂F₂), trifluoromethane (CHF₃), octafluorocyclobutane (C₄F₈), hexafluoroethane (C₂F₆), carbon tetrafluoride (CF₄), or a combination thereof. In an embodiment, the first etchant includes SF₆.

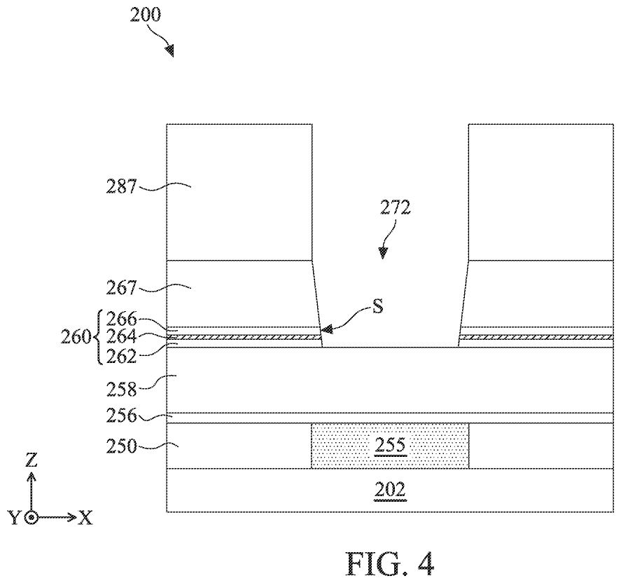

Referring to FIGS. 1 and 4, method 10 includes a block 16 where the MIM structure 260 is etched through to extend the opening 272. This step may also be referred to as a second etch process. In embodiments, the second etch process etches through the MIM structure 260 at a substantially homogeneous rate, resulting in a linear taper profile of a sidewall (S) of the MIM structure 260. It is noted that in some embodiments, the second etch process etches the insulator layer 264 at a rate different from the rate it etches the conductor plate layers 262 and 266, thus the insulator layer 264 may taper differently from the conductor plate layers 262 and 266. However, because each of the conductor plate layers 262 and 266 is thicker than the insulator layer 264, the profile of the sidewall (S) of the MIM structure 260 is dominated by portions of the profile through the conductor plate layers 262 and 266, thus the portion of the opening 272 through the MIM structure 260 has a substantially linear tapering profile. The second etch process may be a dry etch process. A second etchant for the second etch process is selected such that a reaction of the second etchant and the conductor plate layers does not produce any non-volatile byproducts that are not readily removable during the second etch process. In some embodiments, the second etchant is chlorine-based, such as chlorine (Cl₂), hydrogen chloride (HCl), silicon tetrachloride (SiCl₄), carbon tetrachloride (CCl₄), trichloromethane (CHCl₃), boron trichloride (BCl₃), tungsten pentachloride (WCl₅), or a combination thereof. In other words, the second etchant is fluorine-free or fluorine-atom free. In an embodiment, exposed sidewall (S) of the MIM structure 260 is treated with oxygen to form a surface region that is more susceptible for the following etch process. The workpiece 200 is then etched using the second etchant that will form a gaseous product with the oxygen-treated surface region. In an embodiment where the second etchant includes WCl₅, tungsten residue (not depicted) may be left behind on the sidewall (S) of the MIM structure 260. The presence of tungsten residue may be detected using energy-dispersive X-ray fluorescence (XRF).

In some implementations, the second etch process is time-controlled such that it terminates after it etches completely through all of the conductor plate layers in the MIM structure 260. In some instances, the second etch process may extend the opening 272 downward to a level below the MIM structure 260. The second etch process does not cause dishing on the top surface of the third dielectric layer 258 because no non-volatile byproducts are redeposited on the third dielectric layer 258 near the sidewalls of the opening 272. That is, upon conclusion of the second etch process, the bottom surface of the opening 272 is substantially planar. The planar bottom surface of the opening 272 prevents dishing during a third etch process (to be described below).

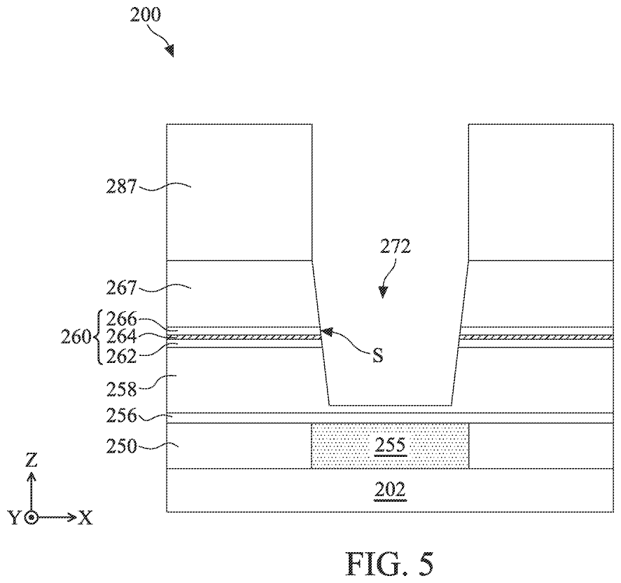

Referring to FIGS. 1 and 5, method 10 includes a block 18 where the third dielectric layer 258 is etched to further extend the opening 272. This step may also be referred to as a third etch process. In embodiments, the third etch process etches the third dielectric layer 258 at a substantially homogeneous rate, resulting in a linear taper profile of a sidewall of the third dielectric layer 258. The third etch process is time-controlled such that it terminates slightly above a top surface of the second dielectric layer 256 (as shown in FIG. 5) or terminates at a top surface of the second dielectric layer 256. The third etch process may be a dry etch process using a third etchant that etches the third dielectric layer 258 and the second dielectric layer 256 faster than the second etchant. Further, the third etchant is selected such that it does not damage the lower contact feature 255. For example, the third etchant does not include chlorine in an example second etch process because chlorine etches oxide and nitride at a rate slower than that of carbon tetrafluoride (CF₄). Chlorine is also known to cause damages to copper, which may be the material of the lower contact feature 255. In some embodiments, the third etchant includes a fluorine-based etchant, such as SF₆, NF₃, CH₂F₂, CHF₃, C₄F₈, C₂F₆, CF₄, or a combination thereof. In some embodiments, the third etch process uses CF₄ as an etchant.

In some embodiments, the first etch process, the second etch process, and the third etch process are performed with a source power (e.g., a radio frequency (RF) source power) and a bias power (e.g., an RF bias power). The source power and the bias power may provide energy to transform etchant gas into plasma, thereby increasing etching capability (e.g., etching rate) of the processes. In some embodiments, the source power is in a range of about 1,000 Watts (W) to about 3,000 W, alternatively in a range of about 1,000 W to about 2,500 W, or alternatively in a range of about 1,500 W to about 2,500 W. In some embodiments, the bias power is in a range of about 1,000 W to about 3,000 W, alternatively in a range of about 1,000 W to about 2,500 W, or alternatively in a range of about 1,500 W to about 2,500 W. If the source power and the bias power (also collectively referred to as “powers”) are too small, the etching capability (e.g., etching rate) may be too small, and the etching rate may be different when the opening 272 has different dimensions (e.g., widths). If the powers are too large, the etching rate may be too large, which increases difficulties in the control of the etch processes.

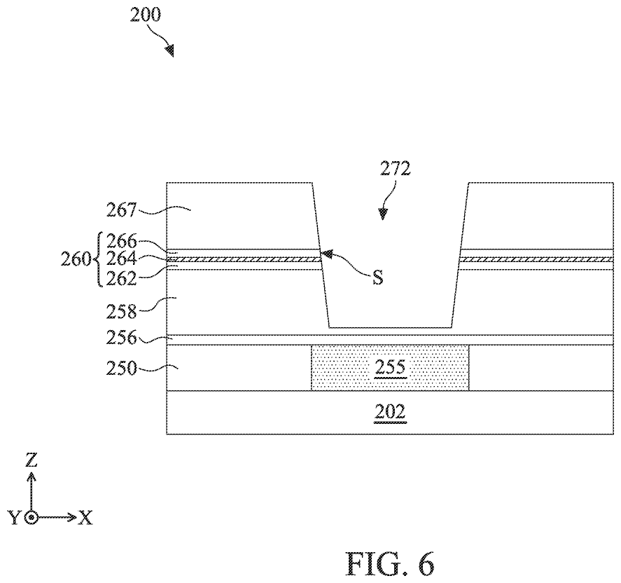

Referring to FIGS. 1 and 6, method 10 includes a block 20 where a first cleaning process is performed to clean the exposed surfaces (e.g., conductive surfaces), such as the sidewall (S) through the MIM structure 260. In an embodiment, sidewalls of the conductor plate layers are recessed at a higher rate than a sidewall of the insulator layer(s). In some examples, the first cleaning process includes a wet cleaning where a first cleaning solution is applied to the workpiece 200. In embodiments, the first cleaning solution includes de-ionized water (DI), hydrogen peroxide (H₂O₂), SC1 (de-ionized water (DI), NH₄OH, and/or H₂O₂), SC2 (DI, HCl, and/or H₂O₂), ozonated de-ionized water (DIWO₃), SPM (H₂SO₄ and/or H₂O₂), SOM (H₂SO₄ and/or O₃), SPOM, H₃PO₄, dilute hydrofluoric acid (DHF), HF, HF/ethylene glycol (EG), HF/HNO₃, NH₄OH, tetramethylammonium hydroxide (TMAH), or a combination thereof. In an embodiment, the first cleaning solution includes H₂O₂. Before or after the first cleaning process, the hard mask layer 287 and the photoresist layer may be selectively removed.

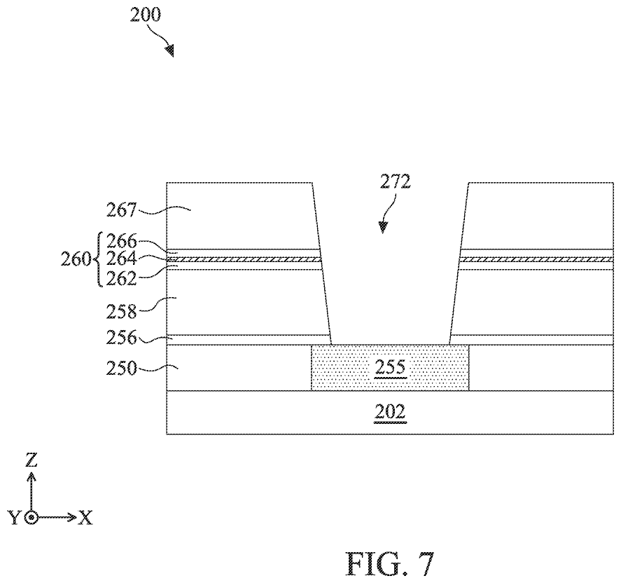

Referring to FIGS. 1 and 7, method 10 includes a block 22 where the second dielectric layer 256 is etched through to expose a top surface of the lower contact feature 255. This step may also be referred to as a fourth etch process. In embodiments depicted in FIG. 5, the third dielectric layer 258 is not etched through in the third etch process, the remaining portion of the third dielectric layer 258 is etched through together with the second dielectric layer 256 in the fourth etch process. In some other embodiments, the third dielectric layer 258 is etched through in the third etch process, and the second dielectric layer 256 is etched through in the fourth etch process. In embodiments, the fourth etch process etches through the second dielectric layer 256 and/or the remaining portion of the third dielectric layer 258 at a substantially homogeneous rate, resulting in a linear taper profile of sidewalls thereof. In some embodiments, profile of the opening 272 is smoothed in the fourth etch process. That is, bumps (not depicted) on sidewalls of the second dielectric layer 256, the third dielectric layer 258, and the fourth dielectric layer 267 exposed to the opening 272 may be removed. The fourth etch process may be a dry etch process using a fluorine-based etchant. The fluorine-based etchant may be the same as the third etchant or may be a different etchant from the third etchant. The fluorine-based etchant may include SF₆, NF₃, CH₂F₂, CHF₃, C₄F₈, C₂F₆, CF₄, or a combination thereof. The fluorine-based etchant may include CF₄. The fourth etch process is time-controlled such that it terminates at a top surface of the lower contact feature 255.

In some embodiments, the fourth etch process is performed with a non-zero source power (e.g., a non-zero RF source power) and a non-zero bias power (e.g., a non-zero RF bias power). In embodiments, the non-zero source power is less than the source power for the first, second, and third etch processes. In embodiments, the non-zero bias power is less than the bias power for the first, second, and third etch processes. In some embodiments, the non-zero source power is in a range of about 200 W to about 1,000 W, alternatively in a range of about 300 W to about 800 W, or alternatively in a range of about 400 W to about 700 W. In some embodiments, the non-zero bias power is in a range of about 200 W to about 1,000 W, alternatively in a range of about 300 W to about 800 W, or alternatively in a range of about 400 W to about 700 W. If the non-zero source power and the non-zero bias power (also be collectively referred to as “non-zero powers”) are too small, the etching capability (e.g., etching rate) may be too small, the second dielectric layer 256 may be etched at a too small rate, such that sidewall of the etched second dielectric layer 256 may taper further from sidewall of the third dielectric layer 258, and the etching rate may be different when the opening 272 has different dimensions (e.g., widths). If the non-zero powers are too great, the non-zero powers may leak through the lower contact feature 255 into the substrate 202 and damage any components therein, and the etching rate may be too great, which increases difficulties in the control of the fourth etch process, and the lower contact feature 255 may be damaged.

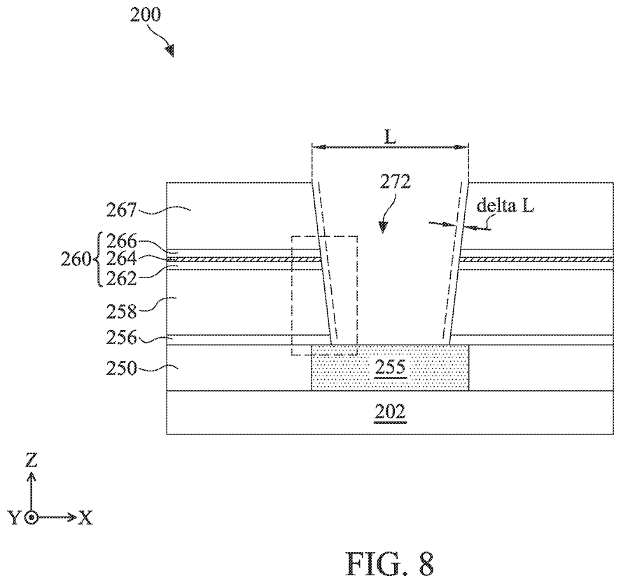

Referring to FIGS. 1 and 8, method 10 includes a block 24 where a second cleaning process is performed to clean the exposed surfaces, such as the sidewall (S) through the MIM structure 260. In an embodiment, the sidewalls of the conductor plate layers are recessed at a higher rate than the sidewall of the insulator layer(s). In addition, the sidewalls of the fourth, the third, and the second dielectric layers 267/258/256 exposed to the opening 272 may be further smoothed in the second cleaning process. As a result, the second cleaning process laterally enlarges the opening 272 by a depth delta L (as shown in FIG. 8, the dotted lines are the position of the sidewalls of the opening 272 before the second cleaning process). The depth delta L may be less than about 1% of a dimensions L of the opening 272. Thus, the second cleaning process may make substantially no change to tapered angles of the sidewalls in the opening 272. In some examples, the second cleaning process includes a wet cleaning where a second cleaning solution is applied to the workpiece 200. In some embodiments, the second cleaning solution includes a copper protector, DI, H₂O₂, SC1, SC2, DIWO₃, SPM, SOM, SPOM, H₃PO₄, DHF, HF, HF/EG, HF/HNO₃, NH₄OH, TMAH, or a combination thereof. In an embodiment, the second cleaning solution includes a copper protector and H₂O₂. The copper protector may include an azole compound, an amine compound, or a combination thereof. In embodiments where the lower contact feature 255 includes copper, the copper protector may react with copper to form a protection layer (e.g., a copper nitride layer) over the top surface of the lower contact feature 255, which prevents underlying copper from further reactions with the second cleaning solution. At this point, the opening 272 is substantially formed.

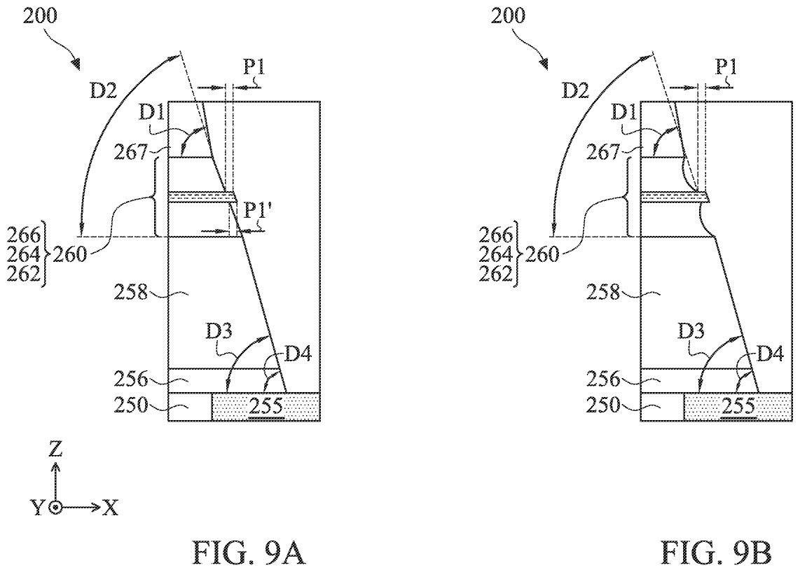

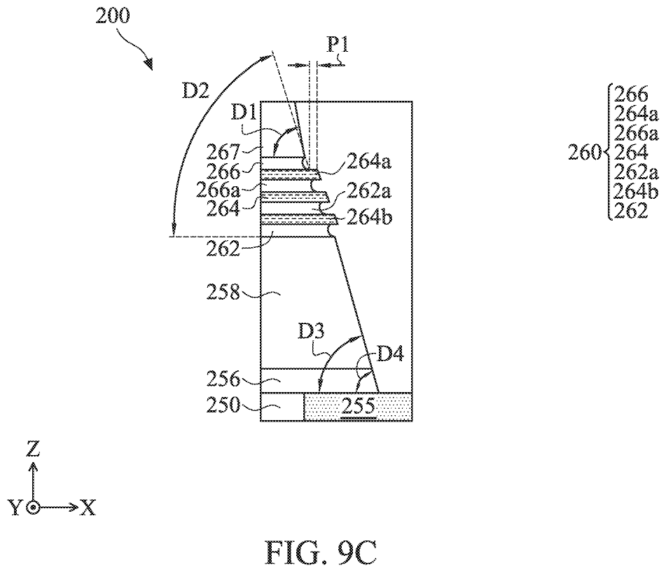

The profile of the opening 272 shown in FIG. 8 is simplified for ease of illustration. In reality, different etch processes may etch different layers at different rates to form tapers of different tapering angles. Detailed sideview illustrations of the opening 272 through the MIM structure 260 are respectively and representatively illustrated in FIGS. 9A, 9B and 9C. Reference is first made to FIG. 9A. The sidewall of the fourth dielectric layer 267 spans a first angle D1 with respect to a topmost surface of the MIM structure 260. The sidewalls of the conductor plate layers 262 and 266 span a second angle D2 with respect to a bottommost surface of the MIM structure 260. The sidewall of the third dielectric layer 258 spans a third angle D3 with respect to a top surface of the lower contact feature 255. The sidewall of the fourth dielectric layer 256 spans a fourth angle D4 with respect to the top surface of the lower contact feature 255. In some embodiments, D1 may be greater than D2 and D3 and D3 may be greater than D2. D3 may be substantially equal to D4. In some instances, a difference between D1 and D2 is less than about 10 degrees (°). In some instances, a difference between D1 and D3 is less than about 5°. Therefore, the opening 272 may be viewed as having three portions—a top portion with a sidewall spanning the first angle D1, a middle portion with a sidewall spanning the second angle D2, and a bottom portion with a sidewall spanning the third angle D3 (or D4). Because the thickness of the MIM structure 260 is relatively small compared to a total thickness of the fourth, the third, and the second dielectric layers 267/258/256, the profile through the MIM structure 260 is a relatively small portion in the total profile of the opening 272, and because the difference between D1 and D3 is less than about 5°, the opening 272 has a substantially linear taper.

Because the sidewalls of the conductor plate layers 262 and 266 are recessed at a higher rate than the sidewall of the insulator layer(s) during the first and the second cleaning processes, the insulator layer 264 protrudes from the top conductor plate layer 266 and the bottom conductor plate layer 262 of the MIM structure 260 by distances P1 and P1′, respectively. In embodiments, P1′ is equal to or greater than P1. In some embodiments, P1 and P1′ are greater than about 5 nm. In embodiments, P1 and P1′ are in a range of about 5 nm to about 20 nm, alternatively in a range of about 5 nm to about 15 nm, alternatively in a range of about 5 nm to about 10 nm. If P1 and P1′ are too small, the first and the second cleaning processes may not sufficiently clean the exposed surfaces in the opening 272. If P1 and P1′ are too large, a barrier layer and/or a seed layer (to be described below) may not be deposited to the sidewalls of the MIM structure 260 conformally, which may cause leakage or voltage breakdown. In some embodiments, a ratio of P1 or P1′ to a thickness of the insulator layer 264 is in a range of about 0.2 to about 5, alternatively in a range of about 0.5 to about 2.

As depicted in FIG. 9B, in some embodiments, the sidewalls of the conductor plate layers 262 and 266 of the MIM structure 260 curve toward the conductor plate layers 262 and 266. This may result from the first and the second cleaning processes. In some embodiments, a sidewall of a lower conductor plate layer (e.g., the bottom conductor plate layer 262) curves more than a sidewall of a higher conductor plate layer (e.g., the top conductor plate layer 266). In embodiments, a line extending from a topmost point to a bottommost point of the sidewalls of the conductor plate layers 262 and 266 of the MIM structure 260 span the second angle D2 with respect to the bottommost surface of the MIM structure 260.

The MIM structure 260 may include more conductor plate layers and more insulator layers, where the profile of the opening 272 remains similar to those described above with reference to FIGS. 9A and 9B, except that each of the insulator layers protrudes from adjacent conductor plate layers by P1. For example, as shown in FIG. 9C, the MIM structure 260 includes four conductor plate layers 266/266a/262a/262 and more three insulator layers 264a/264/264b. The insulator layer 264a protrudes from the conductor plate layers 266/266a by P1/P1′, respectively; the insulator layer 264 protrudes from the conductor plate layers 266a/262a by P2/P2′, respectively; and the insulator layer 264b protrudes from the conductor plate layers 262a/262 by P3/P3′, respectively. In some embodiments, P3′ is equal to or greater than P3, P3 is equal to or greater than P2′, P2′ is equal to or greater than P2, P2 is equal to or greater than P1′, and P1′ is equal to or greater than P1.

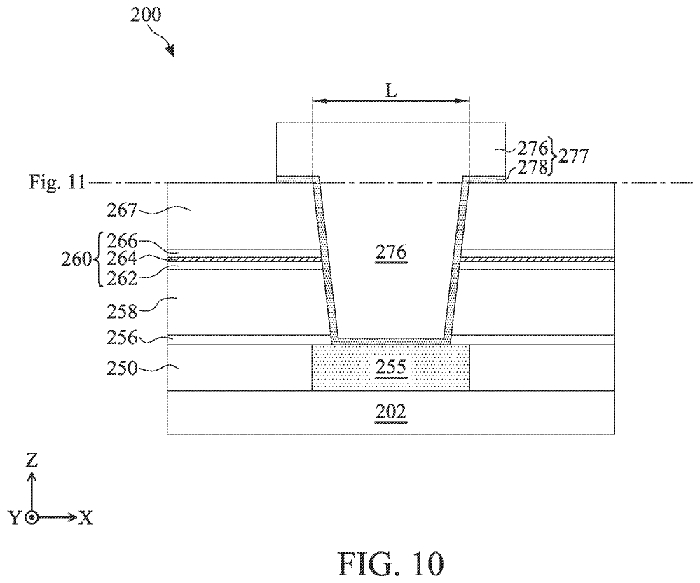

Referring to FIGS. 1 and 10, method 10 includes a block 26 where an upper contact feature 277 (also referred to as a contact via, a metal via, or a metal line) is formed in the opening 272. The upper contact feature 277 includes a metal fill layer 276 that fill the opening 272. In some embodiments, to form the upper contact feature 277, a barrier layer 278 is first conformally deposited over the fourth dielectric layer 267 and into the opening 272 using a suitable deposition technique, such as atomic layer deposition (ALD), physical vapor deposition (PVD) or chemical vapor deposition (CVD) and then the metal fill layer 276 is deposited over the barrier layer 278 using a suitable deposition technique, such as ALD, PVD or ALD. In some embodiments, the barrier layer 278 may be formed of the same material of the conductor plate layers 262 and 266. In those embodiments, the barrier layer 278 may be formed of titanium, tantalum, titanium nitride, or tantalum nitride. The metal fill layer 276 may be formed of copper, aluminum, or an alloy thereof. The deposited barrier layer 278 and the metal fill layer 276 are then patterned to form upper contact feature 277, as illustrated in the example in FIG. 10. In some embodiments, the barrier layer 278 and the metal fill layer 276 are patterned in a two-stage or multiple-stage etch process. A seed layer may be conformally deposited over the fourth dielectric layer 267 and into the opening 272 before forming the metal fill layer 276, by any suitable methods such as PVD. The seed layer may include a metal material, such as the same material as the metal fill layer 276. Because the opening 272 has a substantially linear taper, the barrier layer 278 and/or the seed layer each has substantially conformal thickness. This may raise the reliability level to prevent metal fill layer from penetrating into the MIM structure 260, which may cause voltage breakdown.

In embodiments represented in FIG. 10, the upper contact feature 277 includes an upper portion above the fourth dielectric layer 267 and a lower portion filled in the opening 272. In some embodiments, the upper portion of the upper contact feature 277 has substantially straight sidewalls. In other embodiments not explicitly shown in FIG. 10, the upper portion of the upper contact feature 277 has tapered sidewalls. In some other embodiments, the upper contact feature 277 does not include the upper portion. While not shown in the figures, the upper contact feature 277 may have a square shape, a circular shape, an oval shape, a racetrack shape, a polygon shape, or a rectangular shape when viewed along the Z direction.

At least the upper portion of the upper contact feature 277 is a part of a redistribution layer (RDL) to reroute bond connections between upper and lower layers. The upper contact feature 277 penetrates through, from top to bottom, the fourth dielectric layer 267, the MIM structure 260, the third dielectric layer 258, and the second dielectric layer 256. The upper contact feature 277 makes electrical contact with the lower contact feature 255. The upper contact feature 277 may be electrically coupled to or insulated from any of the conductor plate layers of the MIM structure 260.

While not explicitly shown in FIG. 10, the shape and profile of the lower portion of the upper contact feature 277 generally track those of the opening 272. That is, the lower portion of the upper contact feature 277 will track the taper profile illustrated in FIGS. 9A, 9B and 9C. Detailed descriptions in this regard are omitted for brevity.

Referring to FIG. 1, method 10 includes a block 28 where further processes may be performed. Such further processes may include formation of a passivation structure over the upper contact feature 277 and over the fourth dielectric layer 267. The passivation structure may include one or more passivation layers, which may include one or more plasma-enhanced oxide layers, one or more undoped silica glass layers, silicon nitride (SiN), or a combination thereof. Further processes may also include formation of openings through the passivation layers, deposition of one or more polymeric material layers, patterning of the one or more polymeric material layers, deposition of an under-bump-metallurgy (or under-bump-metallization, UBM) layer, deposition of a copper-containing bump layer, deposition of a cap layer, deposition of a solder layer, and reflowing of the solder layer. These further processes form contact structures for connection to external circuitry.

The lower portion of the upper contact feature 277 in FIG. 10 may have any shapes, such as substantially rectangular or substantially circular when viewed from the top. Also, in some embodiments, the method includes forming multiple upper contact features 277 in the workpiece 200 at the same time. Each of the upper contact features 277 is electrically connected to a lower contact feature (not depicted) similar as the lower contact feature 255. Those lower contact features may be disposed at different pattern loadings.

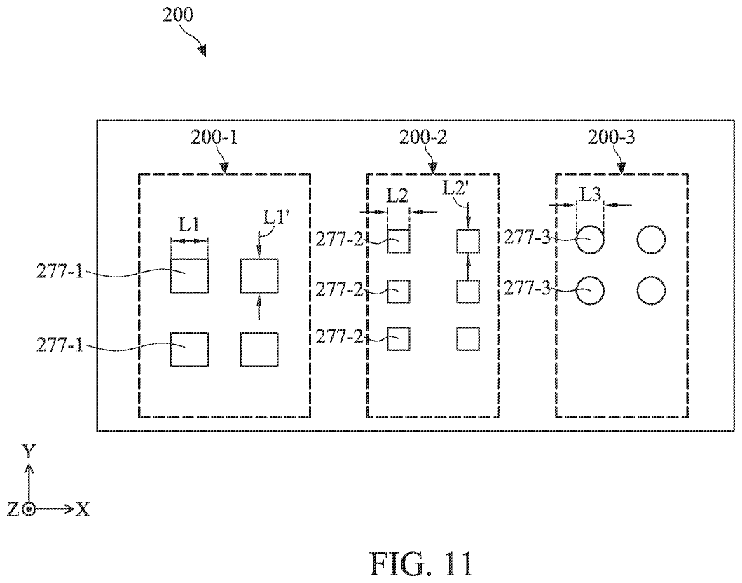

Reference is now made to FIG. 11, which is a cross-sectional view of the workpiece 200 including multiple upper contact features 277-1, 277-2, 277-3 disposed in three regions 200-1, 200-2, and 200-3, respectively, on the X-Y plane through the fourth dielectric layer 267. Each of the upper contact features 277-1, 277-2, 277-3 may be made by the same methods of making the upper contact feature 277 as described above, and thus may have the same material and profile as the upper contact feature 277. In some embodiments, the upper contact features 277-1, 277-2, 277-3 are made simultaneously from the same processes. In some embodiments, the upper contact features 277-1 and 277-2 are substantially rectangular as representatively shown in FIG. 11. The rectangular cross-section of the upper contact features 277-1 has a first dimension L1 (also referred to as a first width L1) and a second dimension L1′ (also referred to as a first length L1′), and the rectangular cross-section of the upper contact features 277-2 has a third dimension L2 (also referred to as a second width L2) and a fourth dimension L2′ (also referred to as a second length L2′). In some instances, L1 may be identical to L1′, and L2 may be identical to L2′. In some other embodiments, the upper contact features 277-3 are substantially circular as representatively shown in FIG. 11. The circular cross-section of the upper contact features 277-3 has a fifth dimension L3 (also referred to as a diameter L3). In some implementations, L1, L1′, L2, L2′, and L3 are between about 500 nm and about 3000 nm. In some embodiments, L1, L2, and L3 are different. A ratio of L1/L2 or L1/L3 may be in a range of about 1 to about 6. If the ratio is too large, the etch rate in forming openings for the upper contact features 277-1 may be greater than the etch rate in forming the openings for the upper contact features 277-2 or 277-3. This may cause heights of the upper contact features 277-1 to be greater than heights of the upper contact features 277-2 or 277-3, and more variation of the dimensions (e.g., widths, lengths, diameters) of the upper contact features 277-1, 277-2, and 277-3. Although only three regions 200-1, 200-2, and 200-3 are depicted, the workpiece 200 may include any number of regions, which may be in any relative positions, and each of which may include any number of the upper contact features. The upper contact features in different regions may have different shapes and dimensions.

The method 10 may include controlling the powers, the non-zero powers, flow rates and compositions of the etchants, pressure, and temperature, etc. during the first through the fourth etch processes, such that the openings with different dimensions (e.g., L1, L2, L3) are extended downward at similar etching rates through the processes. Therefore, depths of the openings with different dimensions are controlled to be similar during different steps in the processes. For example, the non-zero powers and the composition and flow rates of the fourth etchant may be selected, such that the etching rate of the second dielectric layer 256 in the openings with different dimensions are similar. Therefore, the openings with different dimensions terminate the same level (e.g., at the top surfaces of the lower contact features) at the end of the fourth etch process. In another example, the power and composition and flow rate of the second etchant is selected, such that the MIM structure 260 exposed in the openings with different dimensions are etched at similar etching rates. At the end of the second etch process, the openings with different dimensions terminate at the same level (e.g., at the top surface of the third dielectric layer 258.

Methods and semiconductor devices according to the present disclosure provide advantages. For example, methods of the present disclosure result in substantially linear taper profiles of the openings, thus the barrier layer and/or the seed layer of the upper contact features formed therein are conformal, which raises the reliability level to prevent metal fill layer from penetrating into the MIM structure, thus avoids voltage breakdown. In addition, the methods disclosed herein may produce the upper contact features with different dimensions at the same time and thus save time and/or cost in the fabrication.

One aspect of the present disclosure involves a method. The method includes providing a workpiece. The workpiece includes a substrate, a first dielectric layer over the substrate, a lower contact feature vertically extending through the first dielectric layer, a second dielectric layer over the lower contact feature and the first dielectric layer, a third dielectric layer over the second dielectric layer, a metal-insulator-metal (MIM) structure over the third dielectric layer, and a fourth dielectric layer over the MIM structure. The method further includes performing a first etch process to form an opening that extends through the fourth dielectric layer to expose the MIM structure, performing a second etch process to extend the opening through the MIM structure to expose the third dielectric layer, performing a third etch process to further extend the opening into the third dielectric layer, and performing a fourth etch process to further extend the opening through the third dielectric layer and the second dielectric layer to expose the lower contact feature. The first etch process includes a first etchant, the second etch process includes a second etchant, and the third and the fourth etch processes include a third etchant. The first etchant and the third etchant include fluorine, the second etchant does not include fluorine, and performing the fourth etch process includes applying a non-zero bias power and a non-zero source power to the workpiece.

In some embodiments, the non-zero bias power is in a range of about 200 Watts (W) to about 1,000 W, and the non-zero source power is in a range of about 200 W to about 1,000 W. In some embodiments, the method further includes performing a first cleaning process after performing the third etch process, performing a second cleaning process after performing the fourth etch process, and forming a contact via through the opening to be in direct contact with the lower contact feature. In some embodiments, performing the second cleaning process includes applying a cleaning solution including hydrogen peroxide and a copper protector to the workpiece. The copper protector includes an azole compound, an amine compound, or combinations thereof. In some embodiments, the second etchant includes chlorine, hydrogen chloride (HCl), silicon tetrachloride (SiCl₄), carbon tetrachloride (CCl₄), trichloromethane (CHCl₃), boron trichloride (BCl₃), tungsten pentachloride (WCl₅), or combinations thereof. In some embodiments, the lower contact feature includes copper. In some embodiments, performing the first etch process and performing the second etch process include applying a second bias power and a second source power to the workpiece. In some embodiments, the second bias power is greater than the non-zero bias power and is in a range of about 1,000 W to about 3,000 W, and the second source power is greater than the non-zero source power and is in a range of about 1,000 W to about 3,000 W. In some embodiments, the first etchant and the third etchant each includes sulfur hexafluoride (SF₆), nitrogen trifluoride (NF₃), difluoromethane (CH₂F₂), trifluoromethane (CHF₃), octafluorocyclobutane (C₄F₈), hexafluoroethane (C₂F₆), carbon tetrafluoride (CF₄), or a combination thereof. In some embodiments, the second dielectric layer includes silicon carbon nitride (SiCN), and the third dielectric layer and the fourth dielectric layer include silicon nitride (SiN). In some embodiments, the MIM structure includes a conductor plate layer formed of titanium nitride, tantalum nitride, titanium, or tantalum, and an insulator layer formed of zirconium oxide, hafnium oxide, aluminum oxide, tantalum oxide, silicon oxide, or titanium oxide.

Another aspect of the present disclosure involves a method. The method includes providing a workpiece. The workpiece includes a substrate, a first dielectric layer over the substrate, a lower contact feature horizontally surrounded by the first dielectric layer, a second dielectric layer over the lower contact feature and the first dielectric layer, a third dielectric layer over the second dielectric layer, a metal-insulator-metal (MIM) structure over the third dielectric layer, and a fourth dielectric layer over the MIM structure. The MIM structure includes an insulator layer sandwiched by two conductor plate layers. The method further includes performing a first etch process to form an opening extending through the fourth dielectric layer and the MIM structure, and into the third dielectric layer, performing a second etch process to extend the opening through the third dielectric layer and the second dielectric layer to expose the lower contact feature, and performing a cleaning process. After the cleaning process, the insulator layer protrudes from the two conductor plate layers. The first etch process includes a first etchant including chlorine, the second etch process includes a second etchant free of chlorine, and performing the second etch process includes applying a non-zero bias power and a non-zero source power to the workpiece.

In some embodiments, in the cleaning process, the two conductor plate layers are etched at a higher etching rate than the insulator layer. In some embodiments, performing the cleaning process includes laterally enlarging the opening. In some embodiments, the lower contact feature is a first lower contact feature, the opening is a first opening. The workpiece further includes a second lower contact feature horizontally surrounded by the first dielectric layer. The second dielectric layer is further over the second lower contact feature. Performing the first etch process further forms a second opening extending through the fourth dielectric layer and the MIM structure, and into the third dielectric layer. Performing the second etch process further extends the second opening through the third dielectric layer and the second dielectric layer to expose the second lower contact feature. The first and the second openings have different sizes.

Still another aspect of the present disclosure involves a device including a lower contact feature over a substrate, a first dielectric layer over the lower contact feature, a metal-insulator-metal (MIM) structure over the first dielectric layer, a second dielectric layer over the MIM structure, and a conductive feature extending through the second dielectric layer, the MIM structure, and the first dielectric layer and electrically coupled to the lower contact feature. The MIM structure includes a first conductor plate layer, a second conductor plate layer over the first conductor plate layer, and an insulator layer between the first and the second conductor plate layers. The conductive feature interfaces with the first conductor plate layer on a first interface and with the second conductor plate layer on a second interface. The insulator layer extends beyond the first interface and the second interface by a distance greater than about 5 nm, and the insulator layer directly contacts the conduct feature on top, bottom, and side surfaces of the first insulator layer.

In some embodiments, the insulator layer includes a high-k dielectric material. In some embodiments, the first interface and the second interface curve toward the first conductor plate layer and the second conductor plate layer, respectively. In some embodiments, the first conductor plate layer and the second conductor plate layer include titanium nitride (TiN). In some embodiments, the conductive feature interfaces with the first dielectric layer on a first sidewall, with the MIM structure on a second sidewall, and with the second dielectric layer on a third sidewall. The second sidewall spans an angle theta-2 with a bottommost surface of the MIM structure, the third sidewall spans an angle theta-1 with a topmost surface of the MIM structure. A difference between the angle theta-1 and the angle theta-2 is less than about 10 degrees (°). In some embodiments, the first sidewall spans an angle theta-3 with a top surface of the lower contact feature. A difference between the angle theta-1 and the angle theta-3 is less than about 5°.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a workpiece comprising:
a substrate,
a first dielectric layer over the substrate,
a lower contact feature vertically extending through the first dielectric layer,
a second dielectric layer over the lower contact feature and the first dielectric layer,
a third dielectric layer over the second dielectric layer,
a metal-insulator-metal (MIM) structure over the third dielectric layer, and
a fourth dielectric layer over the MIM structure;
performing a first etch process to form an opening that extends through the fourth dielectric layer to expose the MIM structure;
performing a second etch process to extend the opening through the MIM structure to expose the third dielectric layer;
performing a third etch process to further extend the opening into the third dielectric layer; and
performing a fourth etch process to further extend the opening through the third dielectric layer and the second dielectric layer to expose the lower contact feature,
wherein the first etch process comprises a first etchant, the second etch process comprises a second etchant, and the third and the fourth etch processes comprise a third etchant,
wherein the first etchant and the third etchant comprise fluorine,
wherein the second etchant does not include fluorine, and
wherein performing the fourth etch process comprises applying a non-zero bias power and a non-zero source power to the workpiece.

2. The method of claim 1, wherein the non-zero bias power is in a range of about 200 Watts (W) to about 1,000 W, and the non-zero source power is in a range of about 200 W to about 1,000 W.

3. The method of claim 1, further comprising:
performing a first cleaning process after performing the third etch process;
performing a second cleaning process after performing the fourth etch process; and
forming a contact via through the opening to be in direct contact with the lower contact feature.

4. The method of claim 3, wherein performing the second cleaning process comprises applying a cleaning solution including hydrogen peroxide and a copper protector to the workpiece, wherein the copper protector comprises an azole compound, an amine compound, or combinations thereof.

5. The method of claim 1, wherein the second etchant comprises chlorine, hydrogen chloride (HCl), silicon tetrachloride (SiCl₄), carbon tetrachloride (CCl₄), trichloromethane (CHCl₃), boron trichloride (BCl₃), tungsten pentachloride (WCl₅), or combinations thereof.

6. The method of claim 1, wherein the lower contact feature comprises copper.

7. The method of claim 1, wherein performing the first etch process and performing the second etch process comprise applying a second bias power and a second source power to the workpiece,
wherein the second bias power is greater than the non-zero bias power and is in a range of about 1,000 W to about 3,000 W, and
wherein the second source power is greater than the non-zero source power and is in a range of about 1,000 W to about 3,000 W.

8. The method of claim 1, wherein the first etchant and the third etchant each comprises sulfur hexafluoride (SF₆), nitrogen trifluoride (NF₃), difluoromethane (CH₂F₂), trifluoromethane (CHF₃), octafluorocyclobutane (C₄F₈), hexafluoroethane (C₂F₆), carbon tetrafluoride (CF₄), or a combination thereof.

9. The method of claim 1, wherein the second dielectric layer comprises silicon carbon nitride (SiCN), and the third dielectric layer and the fourth dielectric layer comprise silicon nitride (SiN).

10. The method of claim 1, wherein the MIM structure comprises a conductor plate layer formed of titanium nitride, tantalum nitride, titanium, or tantalum, and an insulator layer formed of zirconium oxide, hafnium oxide, aluminum oxide, tantalum oxide, silicon oxide, or titanium oxide.

11. A method, comprising:
providing a workpiece comprising:
a substrate,
a first dielectric layer over the substrate,
a lower contact feature horizontally surrounded by the first dielectric layer,
a second dielectric layer over the lower contact feature and the first dielectric layer,
a third dielectric layer over the second dielectric layer,
a metal-insulator-metal (MIM) structure over the third dielectric layer, wherein the MIM structure comprises an insulator layer sandwiched by two conductor plate layers, and
a fourth dielectric layer over the MIM structure;
performing a first etch process to form an opening extending through the fourth dielectric layer and the MIM structure, and into the third dielectric layer;
performing a second etch process to extend the opening through the third dielectric layer and the second dielectric layer to expose the lower contact feature; and
performing a cleaning process, such that after the cleaning process, the insulator layer protrudes from the two conductor plate layers,
wherein the first etch process comprises a first etchant including chlorine, the second etch process comprises a second etchant free of chlorine, and
wherein performing the second etch process comprises applying a non-zero bias power and a non-zero source power to the workpiece.

12. The method of claim 11, wherein in the cleaning process, the two conductor plate layers are etched at a higher etching rate than the insulator layer.

13. The method of claim 11, wherein performing the cleaning process comprises laterally enlarging the opening.

14. The method of claim 11, wherein the lower contact feature is a first lower contact feature, the opening is a first opening;
wherein the workpiece further comprises a second lower contact feature horizontally surrounded by the first dielectric layer;
wherein the second dielectric layer is further over the second lower contact feature;
wherein performing the first etch process further forms a second opening extending through the fourth dielectric layer and the MIM structure, and into the third dielectric layer;
wherein performing the second etch process further extends the second opening through the third dielectric layer and the second dielectric layer to expose the second lower contact feature; and
wherein the first and the second openings have different sizes.

15. A device, comprising:
a lower contact feature over a substrate;
a first dielectric layer over the lower contact feature;
a metal-insulator-metal (MIM) structure over the first dielectric layer;
a second dielectric layer over the MIM structure; and
a conductive feature extending through the second dielectric layer, the MIM structure, and the first dielectric layer and electrically coupled to the lower contact feature,
wherein the MIM structure comprises a first conductor plate layer, a second conductor plate layer over the first conductor plate layer, and an insulator layer between the first and the second conductor plate layers,
wherein the conductive feature interfaces with the first conductor plate layer on a first interface and with the second conductor plate layer on a second interface,
wherein the insulator layer extends beyond the first interface and the second interface by a distance greater than about 5 nm, and the insulator layer directly contacts the conduct feature on top, bottom, and side surfaces of the first insulator layer.

16. The device of claim 15, wherein the insulator layer comprises a high-k dielectric material.

17. The device of claim 15, wherein the first interface and the second interface curve toward the first conductor plate layer and the second conductor plate layer, respectively.

18. The device of claim 15, wherein the first conductor plate layer and the second conductor plate layer comprise titanium nitride (TiN).

19. The device of claim 15, wherein the conductive feature interfaces with the first dielectric layer on a first sidewall, with the MIM structure on a second sidewall, and with the second dielectric layer on a third sidewall,
wherein the second sidewall spans an angle theta-2 with a bottommost surface of the MIM structure, the third sidewall spans an angle theta-1 with a topmost surface of the MIM structure, and wherein a difference between the angle theta-1 and the angle theta-2 is less than about 10 degrees (°).

20. The device of claim 19, wherein the first sidewall spans an angle theta-3 with a top surface of the lower contact feature, wherein a difference between the angle theta-1 and the angle theta-3 is less than about 5°.
